(19) United States
(12) Patent Application Publication
(10) Pub. No.: US 2026/0178198 A1
(43) Pub. Date: Jun. 25, 2026

(54) NONVOLATILE MEMORY AND STORAGE DEVICE

(71) Applicant: Samsung Electronics Co., Ltd., Suwon-si (KR)

(72) Inventors: Sundong KIM, Suwon-si (KR); Syungki LEE, Suwon-si (KR); Hyunjoo JUNG, Suwon-si (KR)

(73) Assignee: Samsung Electronics Co., Ltd., Suwon-si (KR)

(21) Appl. No.: 19/285,021

(22) Filed: Jul. 30, 2025

(30) Foreign Application Priority Data
Dec. 20, 2024 (KR) 10-2024-0192233

(51) Int. Cl. G06F 3/06; G11C 16/26

(52) U.S. Cl. CPC G06F 3/0611; G06F 3/0688; G11C 16/26

(57) ABSTRACT

Provided is a nonvolatile memory including a plurality of planes including a plurality of word lines, a plurality of bit lines, and a plurality of memory cells connected to the plurality of word lines and the plurality of bit lines; an input/output controller configured to receive commands and addresses, input/output data, and set each plane to a ready status or a busy status; a control logic circuit configured to control the plurality of planes based on commands, and detect a fixed-time read command; and a status delay logic configured to determine a target plane and a bit level based on an address received with the fixed-time read command, and determine a delay time based on the bit level, and the input/output controller is configured to change the target plane from the ready status to the busy status, and restore the target plane from the busy status to the ready status.

### CROSS-REFERENCE TO RELATED APPLICATION(S)

This application claims benefit of priority to Korean Patent Application No. 10-2024-0192233 filed on Dec. 20, 2024, in the Korean Intellectual Property Office, the disclosure of which is incorporated herein by reference in its entirety.

### BACKGROUND

Example embodiments relate to a nonvolatile memory and a storage device including the nonvolatile memory.

In order for a storage device to satisfy Quality of Service (QoS), latency as well as throughput may be beneficial. Specifically, a storage device may be required to have a latency within a set time for responding to an input/output request from a host. In order to ensure the latency of individual input/output requests, the storage device may schedule commands to access nonvolatile memories.

The storage device may include a plurality of nonvolatile memories connected to a plurality of channels, and each of the plurality of nonvolatile memories may include planes. In order to improve performance, the storage device may interleave commands so that the commands may be processed in parallel in the plurality of planes.

### SUMMARY

Various example embodiments provide a nonvolatile memory capable of preventing (or reducing) delay of read commands by providing responses in the same order as an order in which the read commands were received, despite a difference in read operation time between planes, due to internal factors.

Various example embodiments provide a storage device including the nonvolatile memory and capable of ensuring (or configured to meet) QoS for input/output requests.

Some example embodiments provide a nonvolatile memory including a plurality of planes, each plane of the plurality of planes including a plurality of bit lines, and a plurality of memory cells connected to the plurality of word lines and the plurality of bit lines, wherein the plurality of memory cells are multi-level cells; an input/output controller configured to receive commands and addresses through a channel, input/output data through the channel, and set each plane of the plurality of planes to a ready status or a busy status; a control logic circuit configured to control the plurality of planes based on commands, and detect a fixed-time read command, among the commands; and a status delay logic configured to determine a target plane and a bit level based on an address received with the fixed-time read command, and determine a delay time based on the bit level, wherein the input/output controller is configured to change the target plane from the ready status to the busy status when a read operation time is started in response to the fixed-time read command in the target plane, and restore the target plane from the busy status to the ready status after the delay time has elapsed based on the read operation time having ended.

Some example embodiments of inventive concepts provide a nonvolatile memory including a plurality of planes, each plane of the plurality of planes including a plurality of word lines, a plurality of bit lines, and a plurality of memory cells connected to the plurality of word lines and the plurality of bit lines; a control logic circuit configured to control the plurality of planes based on commands and detect a plurality of fixed-time read commands for the plurality of planes; and an input/output controller configured to change the plurality of planes from a ready status to a busy status in an order in which the plurality of fixed-time read commands are received, and restore the busy status to the ready status after respective delay times have elapsed based on respective read operation times of the plurality of fixed-time read command having ended, wherein an order in which the plurality of fixed-time lead commands are received and an order in which the plurality of planes are restored from the busy status to the ready status are consistent with each other.

Some example embodiments of inventive concepts provide a storage device including a plurality of nonvolatile memories, each nonvolatile memory of the nonvolatile memories including a storage controller configured to control the plurality of nonvolatile memories; and a plurality of channels configured to connect the storage controller and the plurality of nonvolatile memories, wherein the storage controller is configured to receive a plurality of read requests from a host, schedule fixed-time read commands for the plurality of nonvolatile memories based on target latencies of the plurality of read requests, and interleave the fixed-time read commands for the plurality of planes included in the plurality of nonvolatile memories based on a scheduled order, and each of the plurality of nonvolatile memories is configured to perform fixed-time read operations in parallel on the plurality of planes in response to the fixed-time read commands, and provide responses for the fixed-time read commands to the storage controller in a same order as an order in which the fixed-time read commands are received.

A nonvolatile memory according to some example embodiments of the present inventive concepts may provide responses in the same order as an order in which read commands are received by delaying the response time by a time determined based on a length of the read operation time of each plane. Accordingly, it may be possible to prevent (or reduce) a response to a command received earlier from being delayed due to a response to a command that is received later and processed earlier.

A storage device according to some example embodiments of the present inventive concepts may include a plurality of nonvolatile memories, and interleaves read commands with the plurality of nonvolatile memories based on a determined latency of a plurality of read requests, and the plurality of nonvolatile memories may ensure (or meet, or satisfy) QoS for read requests by providing responses to the read commands at a fixed time.

Some example embodiments of inventive concepts provide a method of operation of a nonvolatile memory, the method including receiving, by a nonvolatile memory, a fixed-time read command and an address corresponding to the fixed-time read command, determining, by the nonvolatile memory, a bit level of a target subpage based on the address, determining, by the nonvolatile memory, a delay time based on the bit level, the delay time corresponding to a time at which a busy status is restored to a ready status, and changing, by the nonvolatile memory, a status of a target plane.

In some example embodiments, the changing the status of the target plane includes a first change of the status of the target plane and a second change of the status of the target plane, the first change of the status of the target plane includes changing the status of the target plane from a ready status to a busy status, and the second change of the status of the target plane includes changing the status of the target plane from the busy status to the ready status based on a read operation time of the target plane and the delay time having ended.

Some example embodiments of inventive concepts may include a method of operation of a storage device including receiving, by a storage controller, a plurality of read requests from a host, scheduling, by the storage controller, a plurality of fixed-time read commands based on a target latency of the plurality of read requests, interleaving, by the storage controller, the plurality of fixed-time read commands for a plurality of nonvolatile memories based on a command scheduling order, transmitting, by the storage controller, the plurality of fixed-time read commands to the plurality of nonvolatile memories, performing, by the plurality of nonvolatile memories, fixed-time read operations based on receiving the plurality of fixed-time read commands, transmitting, by the plurality of nonvolatile memories, data to the storage controller, the data corresponding to the plurality of fixed-time read commands, and providing, by the storage controller, a response to the plurality of read requests to the host based on the data.

In some example embodiments, the plurality of read requests include a request of a particular target latency for each read request of the plurality of read requests.

In some example embodiments, the plurality of fixed-time read commands includes a first read command, a second read command, a third read command, and a fourth read command, and the data includes a first data corresponding to the first read command, a second data corresponding to the second read command, a third data corresponding to the third read command, and a fourth data corresponding to the fourth read command.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a view illustrating a storage system according to some example embodiments;

FIG. 2 is a view illustrating a storage device according to some example embodiments;

FIG. 3 is a view illustrating a nonvolatile memory;

FIG. 4 is a view illustrating a structure of a memory block;

FIGS. 5A and 5B are views illustrating read operation times of memory cells for each subpage;

FIGS. 6A and 6B are views illustrating a read command operation of a nonvolatile memory according to some example embodiments;

FIG. 7 is a view illustrating a structure of a nonvolatile memory according to some example embodiments;

FIG. 8 is a view illustrating a storage device according to some example embodiments;

FIG. 9 is a signal diagram illustrating an operation of a nonvolatile memory according to some example embodiments;

FIG. 10 is a flowchart illustrating an operation of a nonvolatile memory according to some example embodiments; and

FIG. 11 is a flowchart illustrating an operation of a storage device according to some example embodiments.

### DETAILED DESCRIPTION

Hereinafter, various example embodiments of inventive concepts will be described with reference to the accompanying drawings.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

When the term “substantially” is used in this specification in connection with a numerical value, it is intended that the associated numerical value includes a manufacturing or operational tolerance (e.g., ±10%) around the stated numerical value. Moreover, when the term “substantially” is used in connection with geometric shapes, it is intended that precision of the geometric shape is not required but that latitude for the shape is within the scope of the disclosure. Further, regardless of whether numerical values or shapes are modified as “substantially,” it will be understood that these values and shapes should be construed as including a manufacturing or operational tolerance (e.g., ±10%) around the stated numerical values or shapes.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to the other elements and/or properties thereof. Elements and/or properties thereof that are “the same” or “equal” to other elements and/or properties thereof will be understood to include elements and/or properties thereof that are identical to, the same as, or equal to the other elements and/or properties thereof within manufacturing tolerances and/or material tolerances (e.g., ±10%). Elements and/or properties thereof that are identical, the same, and/or equal as other elements and/or properties thereof may be structurally the same or substantially the same, functionally the same or substantially the same, and/or compositionally the same or substantially the thereof.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular,” “substantially parallel,” respectively, with regard to the other elements and/or properties thereof.

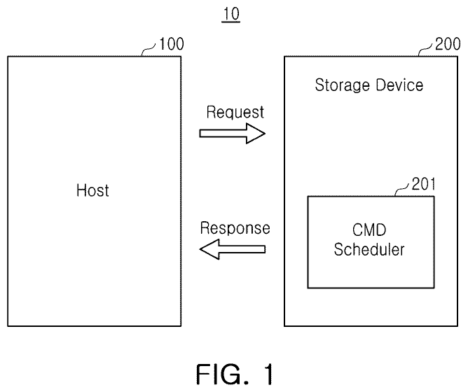

FIG. 1 is a view illustrating a storage system according to some example embodiments.

Referring to FIG. 1, a storage system 10 may include a host 100 and a storage device 200.

The host 100 may include at least one core for processing commands. For example, the host 100 may include an application processor, a microprocessor, a Central Processing Unit (CPU), a processor core, a multi-core processor, a multi-processor, an Application-Specific Integrated Circuit (ASIC), and a Field Programmable Gate Array (FPGA), but example embodiments are not limited thereto.

The storage device 200 may include storage media for storing data in response to a request from the host 100. For example, the storage device 200 may include at least one of a Solid Status Drive (SSD), an embedded memory, and a removable external memory. In some example embodiments, when the storage device 200 is the SSD, the embedded memory, or the external memory, the storage device 200 may further include a nonvolatile memory.

In some example embodiments, when the storage device 200 is the SSD, the storage device 200 may be a device that complies with the non-volatile memory express (NVMe) standard. In some example embodiments, when the storage device 200 is the embedded memory or the external memory, the storage device 200 may be a device that complies with the universal flash storage (UFS) or embedded multi-media card (eMMC) standard.

Each of the host 100 and the storage device 200 may generate packets according to the adopted standard protocol and transmit the packets. For example, the host 100 may provide an input/output request such as a read request or a write request to the storage device 200, and the storage device 200 may provide a response to the input/output request to the host 100.

The storage device 200 providing the response to a host 100 may be required to have a Quality of Service (QoS) above a predetermined level (or it may be beneficial for the storage device 200 to have a QoS above a desired level). For example, the storage device 200 may be required to not only exhibit an input/output throughput above a predetermined level (or it may not only be beneficial for the storage device 200 to exhibit an input/output throughput above a desired level), but also to have a latency within a predetermined time (or a desired time) for a response to an individual input/output request.

The storage device 200 may include a plurality of nonvolatile memories, and may improve the throughput of the input/output requests by interleaving commands for the plurality of nonvolatile memories so that the plurality of nonvolatile memories may operate in parallel. A single nonvolatile memory may include a plurality of planes that may operate in parallel with each other, and may also interleave commands for the plurality of planes included in the single nonvolatile memory.

Additionally or alternatively, the storage device 200 may schedule the commands based on the latency used or requested (or the latency required) for the I/O requests so that individual I/O requests may have latency within a set period.

In an example of FIG. 1, a command scheduler 201 capable of scheduling commands of the storage device 200 is illustrated. The command scheduler 201 may adjust an order of the commands so that commands related to the I/O requests that should be processed first may be processed earlier in the nonvolatile memories.

Due to internal factors of the nonvolatile memory, the read operation time for each read command may vary. In some example embodiments, when the nonvolatile memory is a multi-level cell memory that may store multiple bits of data in one memory cell, the read operation time may vary depending on (or based on) which bit of data is read, e.g., the bit level. For example, in a Triple Level Cell (TLC) memory, the read operation time may vary depending on (or based on) which level of bit among the Most Significant Bit (MSB), the Central Significant Bit (CSB) and the Least Significant Bit (LSB) is read.

In some example embodiments, when the read operation time used or requested (or time required) for each of the read commands processed in parallel varies, there may be cases in which the read operation of a read command received earlier is completed later. Accordingly, there may be cases in which the response to an input/output request that should be processed earlier is delayed.

According to some example embodiments, in nonvolatile memories, regardless of the actual read operation time of the read commands, a fixed-time read command having the same time from starting a read operation for each of the read commands to completing the read operation may be defined.

For example, the fixed time may be determined as the longest time among the read operation times according to different bit levels. Additionally or alternatively, the fixed time read command may refer to a command in which a time between a point in time at which the command is received by the nonvolatile memory and a point in time at which the read operation corresponding to the command is completed, is the same as the fixed time, no matter which bit level of data is read in response to the command. In some example embodiments, when the storage controller first obtains a data item whose read operation is completed earlier from the nonvolatile memory, an order in which the fixed time read commands are received in the nonvolatile memory and an order in which the data items corresponding to the fixed time read commands are outputted externally from the nonvolatile memory may be consistent with each other.

The storage device may schedule the fixed time read commands based on a processing order (or based on a processing order required) for the input/output requests, and may prevent (or reduce) the read command that should be processed earlier from being completed later by outputting the data in the order in which the fixed time read commands are scheduled. The storage device may prevent (or reduce) the delay of the read command and may satisfy the latency set for each input/output request, and as a result, may improve QoS.

Hereinafter, a storage device and a nonvolatile memory according to some example embodiments are described in detail.

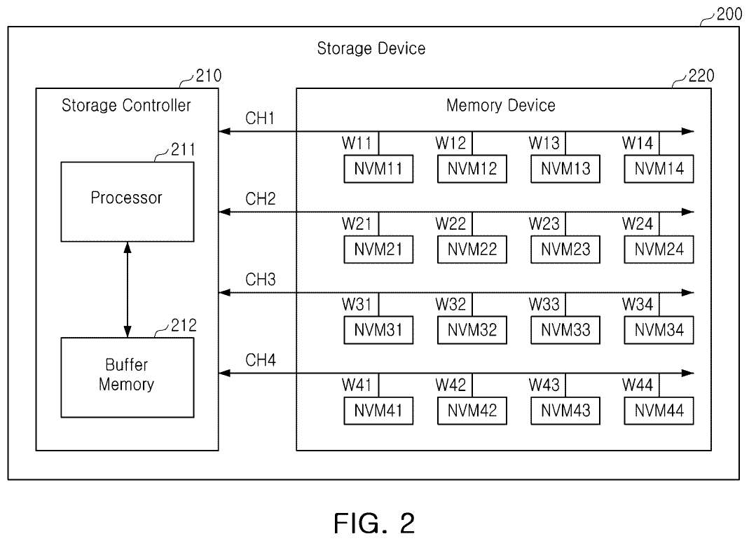

FIG. 2 is a view illustrating a storage device according to some example embodiments.

The storage device 200 of FIG. 2 may correspond to the storage device 200 described with reference to FIG. 1. The storage device 200 may include a storage controller 210 and a memory device 220.

The storage controller 210 may control an overall operation of the storage device 200. For example, the storage controller 210 may store data in the memory device 220 in response to a request from the host 100 as described with reference to FIG. 1, and may provide data stored in the memory device 220 to the host 100 in response to the request from the host 100.

In some example embodiments, when the memory device 220 includes a flash memory, the flash memory may include a 2D NAND memory array or a 3D (or vertical) NAND (VNAND) memory array. For example, the storage device 200 may include various other types of nonvolatile memories. For example, the storage device 200 may be applied with Magnetic RAM (MRAM), Spin-Transfer Torque MRAM, Conductive bridging RAM (CBRAM), FeRAM (Ferroelectric RAM), PRAM (Phase RAM), Resistive RAM, and various other types of memories.

The storage controller 210 may include a processor 211 and a buffer memory 212. The processor 211 may control the storage device 200 by executing firmware. The buffer memory 212 may temporarily store data provided from the host 100 or data output from the memory device 220.

The storage controller 210 may convert a logical address used in the host 100 into a physical address of the memory device 220, and may perform management operations such as garbage collection and wear leveling. Additionally or alternatively, the storage controller 210 may include a command scheduler 201 like that described with reference to FIG. 1. For example, the storage controller 210 may generate commands provided to the memory device 220 based on input/output requests received from the host 100, and may schedule a processing order of the commands based on the latency used or requested (or the latency required) for the input/output requests.

The memory device 220 may include a plurality of nonvolatile memories NVM11 to NVM44. Each of the nonvolatile memories NVM11 to NVM44 may be connected to one of the plurality of channels CH1 to CH4 through a corresponding way. For example, the nonvolatile memories NVM11 to NVM14 may be connected to the first channel CH1 through ways W11 to W14, and the nonvolatile memories NVM21 to NVM24 may be connected to the second channel CH2 through ways W21 to W24.

In some example embodiments, each of the nonvolatile memories NVM11 to NVM44 may be implemented as an memory item (or as an arbitrary memory item) that may operate according to an individual command from the storage controller 210. For example, each of the nonvolatile memories NVM11 to NVM44 may be implemented as a chip or a die.

The storage controller 210 may transmit or receive signals with the memory device 220 through the plurality of channels CH1 to CH4. For example, the storage controller 210 may transmit commands, addresses and data to the memory device 220 through the channels CH1 to CH4, or receive data from the memory device 220.

The storage controller 210 may select one of the nonvolatile memories connected to a corresponding channel through each channel, and may transmit or receive signals with the selected nonvolatile memory. The storage controller 210 may transmit commands, addresses and data to the selected nonvolatile memory through the channel, or receive data from the selected nonvolatile memory.

The storage controller 210 may transmit or receive signals with the memory device 220 through different channels in parallel. For example, the storage controller 210 may transmit another command to the memory device 220 through the second channel CH2 while transmitting the command to the memory device 220 through the first channel CH1. Additionally or alternatively, the storage controller 210 may receive other data from the memory device 220 through the second channel CH2 while receiving data from the memory device 220 through the first channel CH1.

Each of the nonvolatile memories connected to the storage controller 210 through the same channel may perform internal operations in parallel. For example, the storage controller 210 may sequentially transmit a command and an address to the nonvolatile memories NVM11 to NVM14 through the first channel CH1. In some example embodiments, when the command and the address are transmitted to the nonvolatile memories NVM11 to NVM14, each of the nonvolatile memories NVM11 to NVM14 may perform operations according to the command in parallel.

The nonvolatile memories connected to the storage controller 210 through the same channel may sequentially perform data input/output. For example, a read operation may be performed in parallel in the nonvolatile memories NVM11 to NVM14, and data read from the nonvolatile memories NVM11 to NVM14 may be sequentially output through the first channel CH1.

In FIG. 2, the memory device 220 is illustrated as communicating with the storage controller 210 through four channels and including four nonvolatile memories connected to each channel of the memory device 220. However, example embodiments are not limited thereto, and the number of channels and the number of nonvolatile memories connected to one channel may be variously changed.

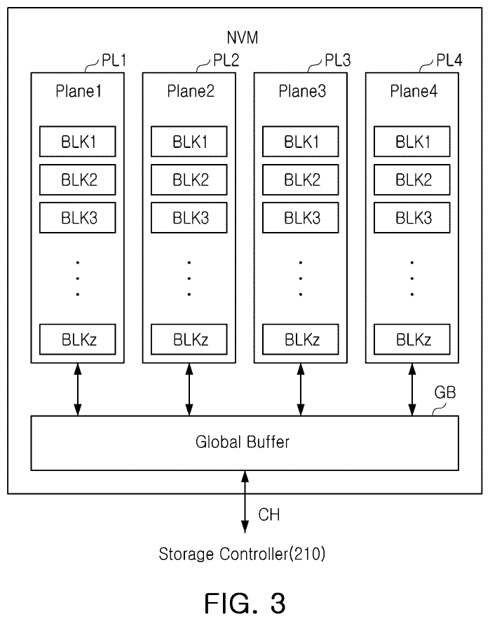

A single nonvolatile memory may process a plurality of commands in parallel. Hereinafter, the structure of the nonvolatile memory is described in more detail with reference to FIG. 3.

FIG. 3 is a view illustrating a nonvolatile memory.

A nonvolatile memory NVM of FIG. 3 may correspond to any of the nonvolatile memories NVM11 to NVM44 described with reference to FIG. 2. Referring to FIG. 3, the nonvolatile memory NVM may include a plurality of planes PL1 to PL4 and a global buffer GB.

Each of the plurality of planes PL1 to PL4 may be a unit (or a minimum unit) in which an operation such as a read operation, a write operation, or an erase operation is performed (or is independently performed). In some example embodiments, when the nonvolatile memory NVM includes a plurality of planes PL1 to PL4, a plurality of command operations may be performed simultaneously and in parallel on each of the plurality of planes PL1 to PL4.

The plurality of planes PL1 to PL4 may include a plurality of memory blocks BLK1 to BLKz. Each of the plurality of memory blocks BLK1 to BLKz may include a plurality of pages. Each of the plurality of pages may include a plurality of memory cells for storing data. The read operation and the write operation may be performed in units of pages, and the erase operation may be performed in units of memory blocks.

The global buffer GB may buffer data to be written to the plurality of planes PL1 to PL4 or may buffer data read from the plurality of planes PL1 to PL4. For example, data read from the plurality of planes PL1 to PL4 may be buffered in the global buffer GB and then may be output to the storage controller 210 through a channel CH. The channel CH of FIG. 3 may correspond to any of the channels CH1 to CH4 described with reference to FIG. 2.

Unlike the plurality of planes PL1 to PL4 that may perform read operations simultaneously, data read from the plurality of planes PL1 to PL4 may be sequentially output through the channel CH. For example, data whose read operation is completed first may be output first.

The read operation time for each read command of the plurality of planes PL1 to PL4 may vary due to internal factors of the nonvolatile memory. In some example embodiments, when a read operation for a read command received later, among the read commands for the plurality of planes PL1 to PL4, is completed earlier, the data for the command received later may be output first.

The channel CH that sequentially outputs data may cause a bottleneck (or a delay) in the nonvolatile memory NVM inputting or outputting data. In some example embodiments, when the read operation for the read command received earlier is completed later, a data output of the read command received earlier may be delayed due to the data being output earlier.

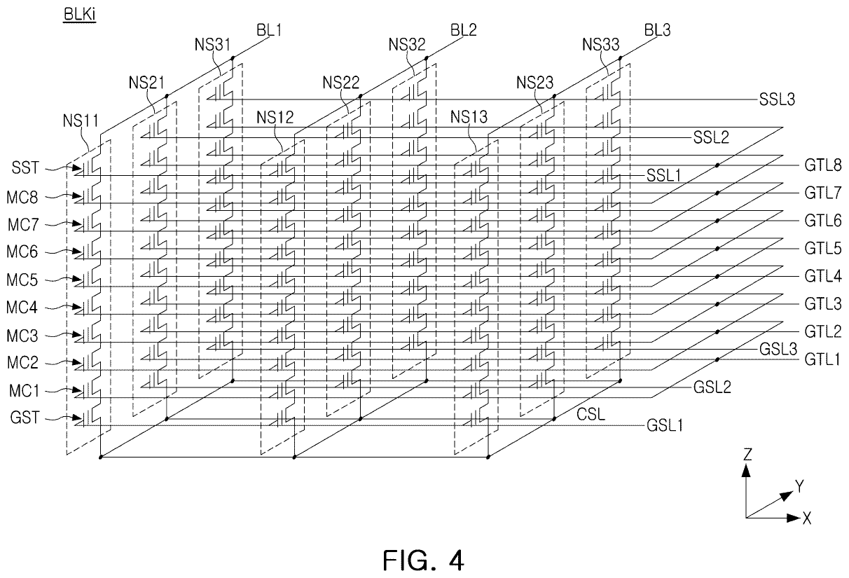

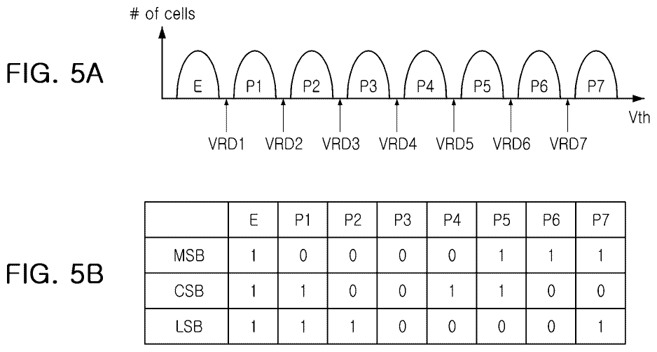

Hereinafter, the read operation time for each read command is described with reference to FIG. 4, FIG. 5A, and FIG. 5B.

FIG. 4 is a view illustrating the structure of a memory block.

FIG. 4 is a view illustrating a 3D V-NAND structure that may be applied to a storage device according to some example embodiments. In some example embodiments, when the nonvolatile memory of the storage device is implemented as a flash memory of the 3D V-NAND type, each of the plurality of memory blocks included in the nonvolatile memory may be expressed by a circuit as illustrated in FIG. 4.

A memory block BLKi illustrated in FIG. 4 represents a three-dimensional memory block formed in a three-dimensional structure on a substrate. For example, the plurality of memory NAND strings included in the memory block BLKi may be formed in a direction, perpendicular to the substrate. The memory block BLKi of FIG. 4 may correspond to any of the memory blocks BLK1 to BLKz described with reference to FIG. 3.

Referring to FIG. 4, the memory block BLKi may include a plurality of memory NAND strings NS11 to NS33 connected between bit lines BL1, BL2 and BL3 and a common source line CSL. Each of the plurality of memory NAND strings NS11 to NS33 may include a string select transistor SST, a plurality of memory cells MC1 to MC8, and a ground select transistor GST. Although FIG. 4 illustrates that each of the plurality of memory NAND strings NS11 to NS33 includes eight memory cells MC1 to MC8, example embodiments are not necessarily limited thereto.

The string select transistor SST may be connected to corresponding string select lines SSL1, SSL2 and SSL3. The plurality of memory cells MC1 to MC8 may be connected to corresponding gate lines GTL1 to GTL8, respectively. The gate lines GTL1 to GTL8 may correspond to word lines, and some of the gate lines GTL1 to GTL8 may correspond to dummy word lines. The ground select transistor GST may be connected to corresponding ground select lines GSL1, GSL2 and GSL3. The string select transistor SST may be connected to corresponding bit lines BL1, BL2 and BL3, and the ground select transistor GST may be connected to the common source line CSL.

Word lines having the same height (e.g., WL1) may be connected in common, and the ground select lines GSL1, GSL2 and GSL3 and the string select lines SSL1, SSL2 and SSL3 may be separated, respectively. In FIG. 4, the memory block BLKi is illustrated as being connected to eight gate lines GTL1 to GTL8 and three bit lines BL1, BL2 and BL3, but example embodiments are not necessarily limited thereto.

FIG. 5A and FIG. 5B are views illustrating a read operation time of each subpage of memory cells.

FIG. 5A is a threshold voltage distribution diagram of memory cells. A horizontal axis of the distribution diagram of FIG. 5A represents a threshold voltage Vth of memory cells, and a vertical axis represents the number of memory cells. FIG. 5A illustrates the threshold voltage distribution of memory cells when the memory cells are Triple Level Cell (TLC) storing three bits of data per memory cell.

Each of the programmed TLCs may have an erase status E and one of the first to seventh program statuses P1 to P7. Each of the erase status E and the first to seventh program statuses P1 to P7 may correspond to different 3-bit data. The 3-bit data corresponding to one program status may include the Most Significant Bit (MSB), the Central Significant Bit (CSB), and the Least Significant Bit (LSB).

FIG. 5B illustrates 3-bit data corresponding to each of the statuses that the TLCs may have. For example, in order to store 3-bit data of (1, 1, 1) in a memory cell, the memory cell may be programmed to have the erase status E. In order to store data of (0, 1, 1) in the memory cell, the memory cell may be programmed to have a first program status P1. In order to store data of (0, 0, 1) in the memory cell, the memory cell may be programmed to have a second program status P2. In order to store data of (0, 0, 0) in the memory cell, the memory cell may be programmed to have a third program status P3. In order to store data of (0, 1, 0) in the memory cell, the memory cell may be programmed to have a fourth program status P4. In order to store data of (1, 1, 0) in the memory cell, the memory cell may be programmed to have a fifth program status P5. In order to store data of (1, 0, 1) in the memory cell, the memory cell may be programmed to have a sixth program status P6. In order to store data of (1, 0, 1) in the memory cell, the memory cell may be programmed to have a seventh program status P7.

Different statuses of the TLC may be distinguished using a plurality of read voltages VRD1 to VRD7. For example, the first read voltage VRD1 may be a voltage for distinguishing between the erase status E and the first program status P1. The second read voltage VRD1 may be a voltage for distinguishing between the first program status P1 and the second program status P2. The third read voltage VRD3 may be a voltage for distinguishing between the second program status P2 and the third program status P3. The fourth read voltage VRD4 may be a voltage for distinguishing between the third program status P3 and the fourth program status P4. The fifth read voltage VRD5 may be a voltage for distinguishing between the fourth program status P4 and the fifth program status P5. The sixth read voltage VRD6 may be a voltage for distinguishing between the fifth program status P5 and the sixth program status P6. The seventh read voltage VRD7 may be a voltage for distinguishing between the sixth program status P6 and the seventh program status P7.

Memory cells connected to one word line may form a physical page. The memory cells may be programmed in units of physical pages. For example, the nonvolatile memory may gradually increase a threshold voltage of memory cells in an erase status E by applying a plurality of program voltages to a word line, and may control the memory cells to have a target status of either the erase status E or the first to seventh program statuses P1 to P7.

A physical page may include subpages having different bit levels. For example, one physical page may include an MSB page formed of MSBs of memory cells, a CSB page formed of CSBs, and an LSB page formed of LSBs.

The MSB page, the CSB page and the LSB page may be read individually. For example, in an example of FIG. 5A and FIG. 5B, when the first and fifth read voltages VRD1 and VRD5 are applied to one word line, the MSB page may be read, when the second, fourth, and sixth read voltages VRD2, VRD4 and VRD6 are applied, the CSB page may be read, and when the third and seventh read voltages VRD3 and VRD7 are read, the LSB page may be read.

The read operation time may vary depending on (or based on) the bit levels of the subpages. For example, the MSB page and the LSB page are read using two read voltages, whereas the CSB page may be read using three read voltages, so that a read operation time of the CSB page may be the longest. The LSB page may have a longer read operation time than the MSB page due to factors other than the number of read voltages used for the read operation.

As described with reference to FIG. 3, a nonvolatile memory may include the plurality of planes on which read operations may be performed in parallel. In some example embodiments, when bit levels of subpages read from the plurality of planes are different, read operation times may be different between the plurality of planes. In some example embodiments, when a read operation time of a plane processing a read command received later is shorter, the read operation of the plane may be completed earlier. In some example embodiments, when an order in which read commands are received in the nonvolatile memory and an order in which the read commands are completed are different from each other, this may adversely affect the QoS of the storage device.

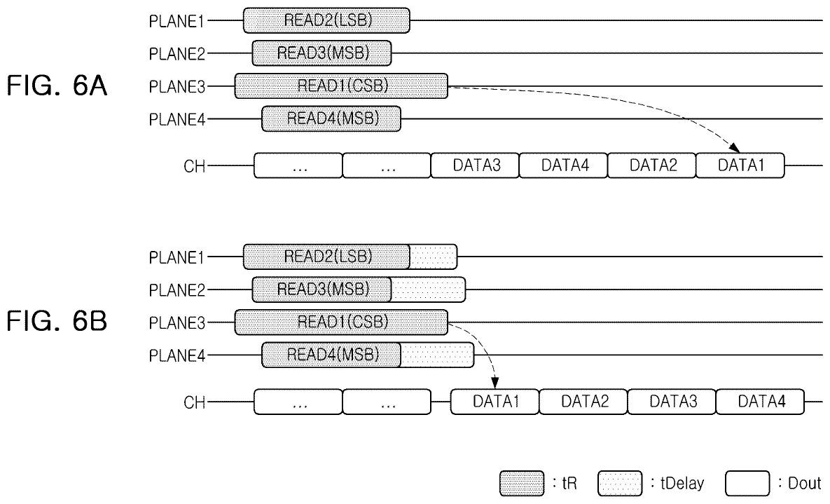

FIG. 6A and FIG. 6B are views illustrating a read command operation of a nonvolatile memory according to a comparative example and some example embodiments.

FIG. 6A illustrates a read command operation of a nonvolatile memory according to a comparative example different from example embodiments.

FIG. 6A illustrates operations of a plurality of planes PLANE1 to PLANE4 included in one nonvolatile memory and a channel CH performing data input/output of the nonvolatile memory and a storage controller over time.

A plurality of read commands READ1 to READ4 may be sequentially received in the nonvolatile memory, and a read operation may be started in the order in which the read commands are received in the plurality of planes PLANE1 to PLANE4. For example, the read operation may be started in the third plane PLANE3, the first plane PLANE1, the second plane PLANE2 and the fourth plane PLANE4 in the order of the first read command READ1, the second read command READ2, the third read command READ3 and the fourth read command READ4.

As described with reference to FIG. 5A and FIG. 5B, when the bit levels of the subpages read by the plurality of read commands READ1 to READ4 are different from each other, the read operation time tR may vary. Since the plurality of planes PLANE1 to PLANE4 may perform the read operation in parallel, there are cases in which the read operation started earlier is completed later. For example, when the first read command READ1 is a read command for the CSB page, and the remaining read commands READ2, READ3 and READ4 are read commands for the LSB page or the MSB page, a read operation for the first read command READ1 may be started first and may be completed last.

The storage controller may obtain first to fourth data items DATA1 to DATA4 corresponding to the first to fourth read commands READ1 to READ4 through the channel CH. The storage controller may obtain a data item corresponding to the read command completed earlier. For example, each of the plurality of planes PLANE1 to PLANE4 may be changed from a ready status to a busy status when the read operation is started, and may be restored from the busy status to the ready status when the read operation is completed. The storage controller may obtain data read from a plane restored to the ready status earlier.

In an example of FIG. 6A, the read operation may be completed in the order of the third read command READ3, the fourth read command READ4, the second read command READ2, and the first read command READ1. The data items read from the nonvolatile memory may be output in the order of the third data item DATA3, the fourth data item DATA4, the second data item DATA2 and the first data item DATA1.

The first data item DATA1 corresponding to the first read command READ1 received first in the nonvolatile memory may be output last. Unlike the read operations that may be performed in parallel for each plane, data output operations Dout may be performed sequentially through the channel CH. Accordingly, even if the read operation for the first read command READ1 is completed somewhat later than other read operations, an output of the first data item DATA1 may be delayed (or significantly delayed). Additionally or alternatively, when a plurality of nonvolatile memories are connected to a single channel and there is a bottleneck (or a delay) due to the data input/output speed of the channel, an output of the first data item DATA1 may be further delayed by the data input/output operations of other nonvolatile memories.

An order in which the plurality of read commands READ1 to READ4 are provided to the nonvolatile memory may be determined based on latency used or requested (or latency required) for input/output requests from the host. For example, a read command for an input/output request that should provide a response earlier may be provided to the nonvolatile memory earlier. In some example embodiments, when a response to the read command provided earlier is delayed (or significantly delayed) in order to first output a response corresponding to the read command provided later, the latency of the input/output request corresponding to the read command may also increase, and thus, it may be difficult for the storage device to ensure the required QoS (or it may be difficult for the storage device to meet the desired QoS).

According to some example embodiments, despite a difference in read operation time according to bit levels of the read commands, the nonvolatile memory may control periods (or periods required) for each of the read commands to be completed to be substantially the same. For example, the read commands may have substantially the same busy status period regardless of the bit level.

FIG. 6B illustrates a read command operation of a nonvolatile memory according to some example embodiments.

Similarly to FIG. 6A, FIG. 6B illustrates operations of the plurality of planes PLANE1 to PLANE4 included in one nonvolatile memory, and the channel CH performing data input/output of the nonvolatile memory and the storage controller over time.

The plurality of read commands READ1 to READ4 may be sequentially received by the nonvolatile memory, and a read operation may be started in the order in which the read commands are received in the plurality of planes PLANE1 to PLANE4. The read operation times tR of the plurality of read commands READ1 to READ4 may vary depending on (or based on) the bit level of the subpage to be read, e.g., a target bit level.

According to some example embodiments, the nonvolatile memory may control the read command to be completed in substantially the same period regardless of the target bit level by delaying the time at which the read operation is completed by a delay time tDelay after the read operation time tR according to the target bit level of the read command.

For example, when the read operation is started in a certain plane, the nonvolatile memory may change the plane from the ready status to the busy status. Additionally or alternatively, the nonvolatile memory may restore the plane from the busy status to the ready status after the read operation time tR has elapsed in the plane and the delay time tDelay has elapsed further.

In some example embodiments, the delay time for the remaining read operation times may be determined based on the longest read operation time, among the read operation times, according to the target bit level. For example, when the read operation time of the CSB page is the longest, the delay time for the read operation of the CSB page may be determined as ‘0.’ Additionally or alternatively, the delay time for the read operation of the LSB page may be determined as a first time at which the sum of the read operation time and the delay time of the LSB page is substantially the same as the read operation time of the CSB page. Similarly, the delay time for the read operation of the MSB page may be determined as a second time at which the sum of the read operation time and the delay time of the MSB page is substantially the same as the read operation time of the CSB page. In some example embodiments, when the read operation time of the LSB page is longer than the read operation time of the MSB page, the second time may be longer than the first time.

In some example embodiments, completion periods of the read operations for each bit level, e.g., the busy status period, may not be the same (or may not be strictly the same). The busy status period for each bit level may have some error within a range in which the order in which the read commands are received and the order in which the read operations are completed are not reversed. For example, the busy status period for each bit level may have an error within the time it takes for the read command to be received.

In an example of FIG. 6B, the second to fourth read commands READ2 to READ4 may be given a delay time tDelay, and completion periods of the read operations of the plurality of read commands READ1 to READ4 may be substantially the same. Accordingly, the read operations may be completed in the same order as an order in which the plurality of read commands READ1 to READ4 are received. The data items read from the nonvolatile memory may be output in the order of the first data item DATA1, the second data item DATA2, the third data item DATA3 and the fourth data item DATA4.

According to some example embodiments, since the response to the read command provided earlier may be output earlier, the problem in which the response to the read command provided earlier is delayed (or significantly delayed) due to the read command provided later may be prevented (or reduced). Accordingly, the latency of individual read commands may be ensured within a predetermined (or desired) level, and the QoS of a storage device including the nonvolatile memory may be improved.

According to some example embodiments, since a delay time may be applied to a read command, there is a case in which a throughput of the nonvolatile memory is reduced (or slightly reduced). However, in the case in which there is a bottleneck (or delay) due to the input/output speed of the channel CH, the throughput reduction of the nonvolatile memory has little effect on the throughput reduction of the storage device, whereas the problem of the latency of individual read commands increasing may be effectively suppressed.

In some example embodiments, whether to apply the delay time to the read operation time may be selected by the storage controller. For example, the nonvolatile memory may support a normal read command and a fixed-time read command. The normal read command may be a read command to which the delay time is not applied regardless of the bit level, as in the comparative example described with reference to FIG. 6A, and the fixed-time read command may be a read command to which the delay time is applied depending on (or based on) the bit level, as described with reference to FIG. 6B, so that an interval between the time at which the read command is received and the time at which the read operation is completed is substantially the same regardless of the bit level.

With reference to FIGS. 5A to 6B, some example embodiments have been described by taking the case in which the nonvolatile memory is a TLC memory as an example, but the present inventive concepts are not limited thereto. The present inventive concepts may be applied to a multi-level cell memory in which one memory cell stores multiple bits of data, but example embodiments are not limited thereto. For example, the present inventive concepts may also be applied to a Quadruple Memory Cell (QLC) memory device. Additionally or alternatively, the present inventive concepts are not necessarily limited to the case of a multi-level cell memory, and may be applied to nonvolatile memories in which the read operation time may vary due to internal factors.

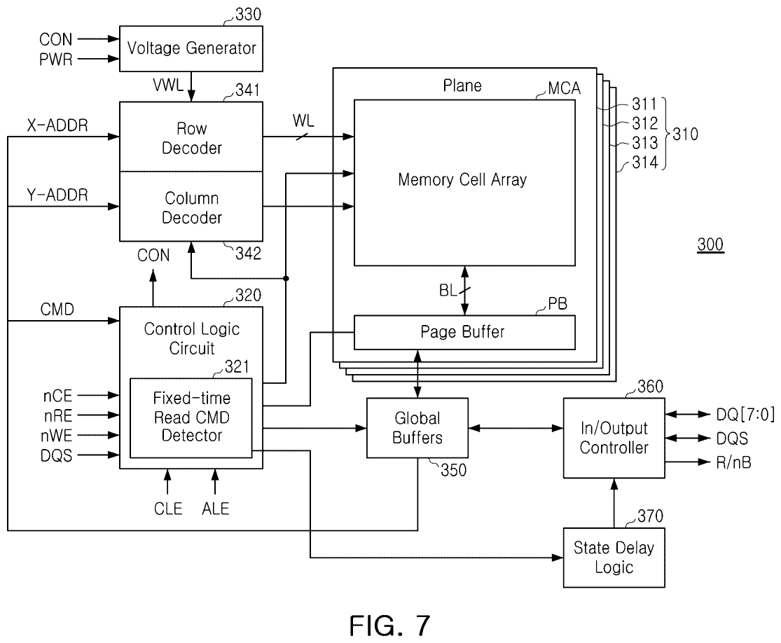

Hereinafter, with reference to FIGS. 7 to 11, a nonvolatile memory according to some example embodiments and a storage device including the nonvolatile memory will be described in more detail.

FIG. 7 is a view illustrating a structure of a nonvolatile memory according to some example embodiments.

A nonvolatile memory 300 of FIG. 7 may correspond to any of the nonvolatile memories NVM11 to NVM44 described with reference to FIG. 2. The nonvolatile memory 300 may include a plurality of planes 310, including planes 311 to 314, a control logic circuit 320, a voltage generation unit 330, a row decoder 341, a column decoder 342, a global buffer 350, an input/output controller 360, and a status delay logic 370.

Each of the plurality of planes 310 may include a memory cell array MCA and a page buffer PB. The memory cell array MCA may include a plurality of word lines, a plurality of bit lines, and a plurality of memory cells connected to the plurality of word lines and the plurality of bit lines. The memory cell array MCA may form the plurality of memory blocks BLK1 to BLKz as described with reference to FIG. 3.

The page buffer PB may be connected to the memory cells through a plurality of bit lines BL. The page buffer PB may operate as a write driver or a sense amplifier depending on (or based on) an operation mode. For example, during a program operation, the page buffer PB may apply a bit line voltage corresponding to data to be programmed to a selected bit line. During a read operation, the page buffer PB may detect data stored in a memory cell by detecting a current or voltage of the selected bit line.

The control logic circuit 320 may control an overall operation of the nonvolatile memory 300. The control logic circuit 320 may output various control signals in response to a command CMD and/or an address ADDR received through the input/output controller 360. For example, the control logic circuit 320 may output a voltage control signal CON, a row address X-ADDR, and a column address Y-ADDR.

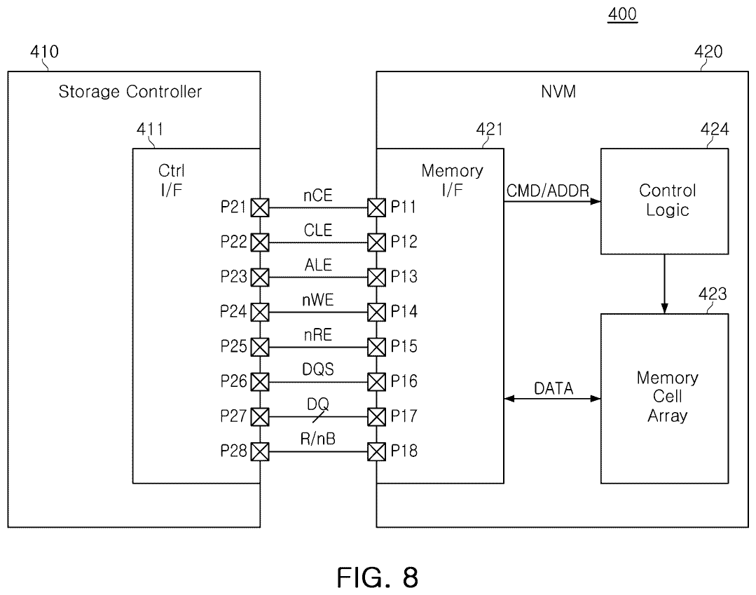

The control logic circuit 320 may operate in response to various control signals received from the outside, like a chip enable signal nCE, a read enable signal nRE, a write enable signal nWE, a command latch enable signal CLE, an address latch enable signal ALE, and a data strobe signal DQS. The various control signals will be described below with reference to FIG. 8.

The voltage generation unit 330 may generate various types of voltages for performing program, read, and erase operations based on the voltage control signal CON. For example, the voltage generation unit 330 may generate a program voltage, a read voltage, a program verification voltage or an erase voltage, as a word line voltage VWL.

The row decoder 341 may select one of a plurality of word lines WL in response to the row address X-ADDR and may select one of a plurality of string select lines. For example, during the program operation, the row decoder 341 may apply a program voltage and a program verification voltage to the selected word line, and during the read operation, the read voltage may be applied to the selected word line.

The column decoder 342 may select at least one bit line among the bit lines BL in response to the column address Y-ADDR.

The input/output controller 360 may input or output a data signal DQ[7:0] and a data strobe signal DQS, and may output a ready/busy signal R/nB. The data signal DQ[7:0] may include data DATA, a command CMD, and an address ADDR. The data strobe signal DQS may provide a reference for the sampling time of the data signal DQ[7:0]. The ready/busy signal R/nB may represent whether the nonvolatile memory is in a ready status or a busy status.

The global buffer 350 may buffer the data signal DQ[7:0] received from the input/output controller 360, or may buffer data output from the plurality of planes 310. The global buffer 350 may correspond to the global buffer GB described with reference to FIG. 3.

The data signal DQ[7:0] buffered in the global buffer 350 may be identified as the command CMD, the address ADDR or data based on a command latch enable signal CLE and an address latch enable signal ALE provided to the control logic circuit 320. The command CMD may be input to the control logic circuit 320, and the address ADDR may be input to the row decoder 341 and the column decoder 342 as the row address X-ADDR and the column address Y-ADDR, respectively. Additionally or alternatively, the data may be provided to any one of the plurality of planes 310.

According to some example embodiments, the status delay logic 370 may determine the delay time of the read command in response to the fixed-time read command as described with reference to FIG. 6B.

For example, the control logic circuit 320 may identify the type of command received from the storage controller and may control an operation of the nonvolatile memory 300 according to the type of command. The control logic circuit 320 may include a fixed-time read command detection unit 321. The fixed-time read command detection unit 321 may provide a control signal to the status delay logic 370 when the command CMD is the fixed-time read command.

The status delay logic 370 may determine a target plane of the fixed-time read command among the plurality of planes 310, based on an address received with the fixed-time read command, and may determine a target bit level. For example, the address may be assigned in units of subpages, and the status delay logic 370 may determine a target subpage based on the address, thereby determining whether the subpage to be read is an MSB page, a CSB page, or an LSB page.

The status delay logic 370 may determine the delay time of the read operation according to the target bit level. As described with reference to FIG. 6B, the delay time of the read operation may be determined as a time at which completion periods of the read operation are substantially the same regardless of the target bit level. In some example embodiments, the delay time according to the target bit level may be experimentally determined in advance.

The status delay logic 370 may change the target plane from the ready status to the busy status when the read operation is started on the target plane, and may restore the busy status of the target plane to the ready status after the read operation time and the predetermined (or desired) delay time have elapsed.

FIG. 8 is a view illustrating a storage device according to some example embodiments.

A storage device 400 may include a storage controller 410 and a nonvolatile memory 420. The storage controller 410 may correspond to the storage controller 210 described with reference to FIG. 2. Additionally or alternatively, the nonvolatile memory 420 may correspond to any of the nonvolatile memories NVM11 to NVM44 described with reference to FIG. 2.

The nonvolatile memory 420 may include first to eighth pins P11 to P18, a memory interface circuit 421, a control logic circuit 422, and a memory cell array 423. The control logic circuit 422 may correspond to the control logic circuit 320 of FIG. 7, and the memory cell array 423 may correspond to the memory cell array MCA of FIG. 7.

The storage controller 410 may include first to eighth pins P21 to P28 and a controller interface circuit 411. The first to eighth pins P21 to P28 may correspond to the first to eighth pins P11 to P18.

The controller interface circuit 411 may provide the chip enable signal nCE to the nonvolatile memory 420 through the first pin P21, and the memory interface circuit 421 may receive the chip enable signal nCE from the storage controller 410 through the first pin P11. The nonvolatile memory 420 may be selected by the chip enable signal nCE. In some example embodiments, when the chip enable signal nCE is in an enabled status, for example, on a low level, the storage controller 410 and the nonvolatile memory 420 may transmit or receive signals through the second to eighth pins P22 to P28 and the second to eighth pins P12 to P18.

The controller interface circuit 411 may transmit the command latch enable signal CLE, the address latch enable signal ALE, and the write enable signal nWE to the nonvolatile memory 420 through the second pin P22 to the fourth pin P24. The controller interface circuit 411 may transmit or receive a data signal DQ to or from the nonvolatile memory 420 through the seventh pin P27. The memory interface circuit 421 may receive the command latch enable signal CLE, the address latch enable signal ALE, and the write enable signal nWE from the storage controller 410 through the second to fourth pins P12 to P14. The memory interface circuit 421 may receive the data signal DQ from the storage controller 410 through the seventh pin P17, or transmit the data signal DQ to the storage controller 410.

The command CMD, the address ADDR and the data may be transmitted through the data signal DQ. In some example embodiments, the data signal DQ may be transmitted through a plurality of data signals. In some example embodiments, the seventh pins P17 and P27 may include a plurality of pins corresponding to each of the plurality of data signals DQ.

The controller interface circuit 411 may transmit a data signal DQ including the command CMD or the address ADDR and a switched write enable signal nWE to the nonvolatile memory 420. The memory interface circuit 421 may obtain the command CMD received from the data signal DQ in an enable section of the command latch enable signal CLE, for example, a high level section, based on a switching time of the write enable signal nWE. The memory interface circuit 421 may obtain the address ADDR received through the data signal DQ in an enable section of the address latch enable signal ALE, for example, a high level section, based on the switching time of the write enable signal nWE.

The controller interface circuit 411 may transmit a read enable signal nRE to the nonvolatile memory 420 through the fifth pin P25, and the memory interface circuit 421 may receive the read enable signal nRE from the storage controller 410 through the fifth pin P15.

The controller interface circuit 411 may receive the data strobe signal DQS from the nonvolatile memory 420 through the sixth pin P26, or may transmit the low data strobe signal DQS to the nonvolatile memory 420. The memory interface circuit 421 may receive the data strobe signal DQS from the storage controller 410 through the sixth pin P16, and may transmit the data strobe signal DQS to the storage controller 410.

In a data DATA output operation of the nonvolatile memory 420, the controller interface circuit 411 may generate a switched read enable signal nRE, and transmit the read enable signal nRE to the nonvolatile memory 420. The memory interface circuit 421 may receive the read enable signal nRE switched by the fifth pin P15 before outputting the data DATA.

The memory interface circuit 421 may generate a data strobe signal DQS, and the data strobe signal DQS may be switched based on the switching of the read enable signal nRE. The memory interface circuit 421 may transmit a data signal DQ including data DATA based on the switching timing of the data strobe signal DQS. The controller interface circuit 411 may receive a data signal DQ including data DATA and a switched data strobe signal DQS from the nonvolatile memory 420. The controller interface circuit 411 may obtain data DATA from the data signal DQ based on the switching time of the data strobe signal DQS.

During the data DATA input operation of the nonvolatile memory 420, the controller interface circuit 411 may generate a switched data strobe signal DQS. The controller interface circuit 411 may transmit the data signal DQ including data DATA to the nonvolatile memory 420 based on the switching time of the data strobe signal DQS.

In some example embodiments, when the data signal DQ including data DATA is received from the storage controller 410, the memory interface circuit 421 may receive a switched data strobe signal DQS and data DATA. The memory interface circuit 421 may obtain data DATA from the data signal DQ based on the switching timing of the data strobe signal DQS.

The memory interface circuit 421 may transmit a ready/busy signal (R/nB; ready/busy output signal) to the storage controller 410 through the eighth pin P18. The memory interface circuit 421 may transmit status information of the nonvolatile memory 420 to the storage controller 410 as the ready/busy signal R/nB. The controller interface circuit 411 may receive a ready/busy signal R/nB from the nonvolatile memory 420 through the eighth pin P28. The controller interface circuit 411 may determine the status information of the nonvolatile memory 420 based on the ready/busy signal R/nB.

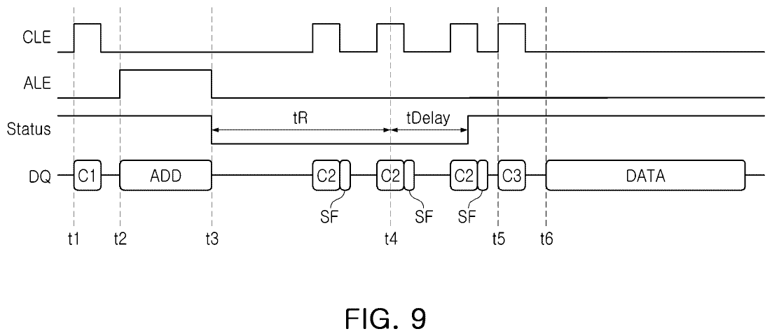

FIG. 9 is a signal diagram illustrating an operation of the nonvolatile memory according to some example embodiments.

FIG. 9 is a view illustrating a command latch enable signal CLE, an address latch enable signal ALE, a status signal Status, and a data signal DQ over time while reading and outputting data from one plane in a nonvolatile memory,

The nonvolatile memory may control to perform a read operation on the target plane in response to a read command for the target plane, and may output data buffered due to the read operation in response to a data output command for the target plane after the read operation is completed.

For example, the command latch enable signal CLE may be enabled between a first point in time t1 and a second point in time t2, and while the command latch enable signal CLE is enabled, the data signal DQ may be input to the nonvolatile memory as a first command C1. The first command C1 may be a fixed-time read command.

An address latch enable signal ALE may be enabled between a second point in time t2 and a third point in time t3, and while the address latch enable signal ALE is enabled, a data signal DQ may be input to a nonvolatile memory as an address ADD. A control logic circuit of the nonvolatile memory may specify a target plane and a target subpage on which the fixed-time read command is to be performed based on the address (ADD).

The read operation may be performed during a read operation time tR between the third point in time t3 and the fourth point in time t4. An input/output controller of the nonvolatile memory may change the status signal Status of the target plane from a ready status to a busy status at the third point in time t3 at which the read operation is started. In some example embodiments, the status signal Status may be a different signal from the ready/busy signal R/nB output to the outside. For example, the status signal Status may be a signal generated and used inside the nonvolatile memory, indicating a ready status or a busy status for each plane unlike the ready/busy signal R/nB.

According to some example embodiments, the status delay logic of the nonvolatile memory may restore the busy status of the target plane to the ready status after the delay time tDelay determined according to the bit level of the target subpage has elapsed, even after the read operation time tR of the target plane has elapsed. In an example of FIG. 9, the status signal Status may be restored from the busy status to the ready status after the delay time tDelay has elapsed from the fourth point in time t4 at which the read operation time has elapsed.

Between the fifth point in time t5 and the sixth point in time t6 after the target plane is restored from the busy status to the ready status, the command latch enable signal CLE may be enabled, and during enabling the command latch enable signal CLE, the data signal DQ may be input to the nonvolatile memory as a third command C3. The third command C3 may be a data output command.

In response to the third command C3, a data output operation may be performed after the sixth point in time t6. For example, data DATA may be output after the sixth point in time t6.

The third command C3 may be provided from a storage controller detecting a state in which the read operation of the target plane is completed. In some example embodiments, the storage controller may provide one or more second commands C2 to the nonvolatile memory between the third point in time t3 and the fifth point in time t5 in order to determine whether the read operation of the target plane is completed. For example, the second command C2 may be provided periodically.

FIG. 9 illustrates a case in which a data signal DQ is input to the nonvolatile memory as the second command C2 during enabling the command latch enable signal CLE. The nonvolatile memory may output a status flag SF indicating whether the target plane is in a ready status or a busy status as the data signal DQ in response to the second command C2.

According to some example embodiments, even after the read operation time tR of the target plane has elapsed, the target plane may maintain the busy status until a predetermined (or desired) delay time tDelay elapses. The nonvolatile memory may output a status flag SF indicating the busy status in response to the second command C2 until the delay time tDelay elapses, and the storage controller may determine that the read operation of the target plane is not completed.

After the delay time tDelay elapses, the nonvolatile memory may output a status flag SF indicating a ready status in response to the second command C2. The storage controller may determine that the read operation of the target plane is completed based on the status flag SF of the ready status, and may provide the third command C3 to the target plane.

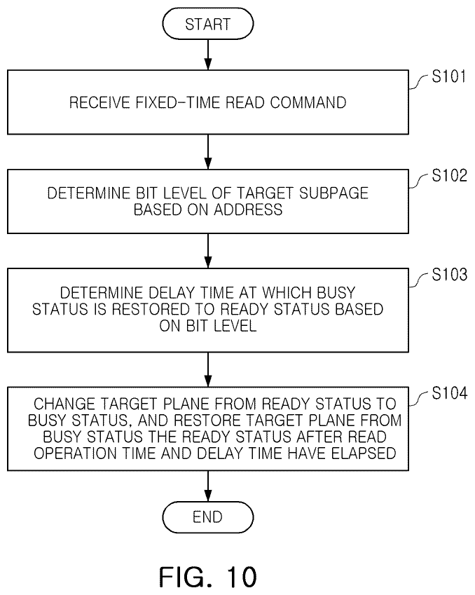

FIG. 10 is a flowchart illustrating an operation of a nonvolatile memory according to some example embodiments.

In operation S101, the nonvolatile memory may receive a fixed-time read command from the storage controller.

The fixed-time read command may be defined in a command set of the nonvolatile memory. The nonvolatile memory may detect a fixed-time read command by analyzing a code received via a data signal during a period in which the command latch enable signal is enabled.

In operation S102, the nonvolatile memory may receive an address corresponding to the fixed-time read command, and may determine a bit level of a target subpage to be read based on the address. For example, when the nonvolatile memory includes TLCs, the bit level may be determined as one of MSB, CSB and LSB.

In operation S103, the nonvolatile memory may determine a delay time at which a busy status is restored to a ready status based on the bit level.

As described above, the delay time tDelay of the target plane may be determined according to the bit level of the target subpage, and may be determined as a time at which read operation completion times are substantially the same regardless of the bit level. In some example embodiments, the delay time tDelay according to the bit level may be determined in advance and may be stored in a status delay logic of the nonvolatile memory.

In operation S104, the nonvolatile memory may change the target plane from the ready status to the busy status, and may restore the target plane from the busy status to the ready status after the read operation time of the target plane and the delay time have elapsed.

According to some example embodiments, the storage controller may obtain data items corresponding to the fixed-time read commands in the order in which a plurality of fixed-time read commands are provided to the nonvolatile memory. Accordingly, it may be possible to prevent (or reduce) the problem in which the response to the read command provided first is delayed due to the response to the read command provided later. Accordingly, the storage device may ensure (or meet) a predetermined (or desired) latency for individual input/output requests from the host, thereby improving the QoS of the storage device.

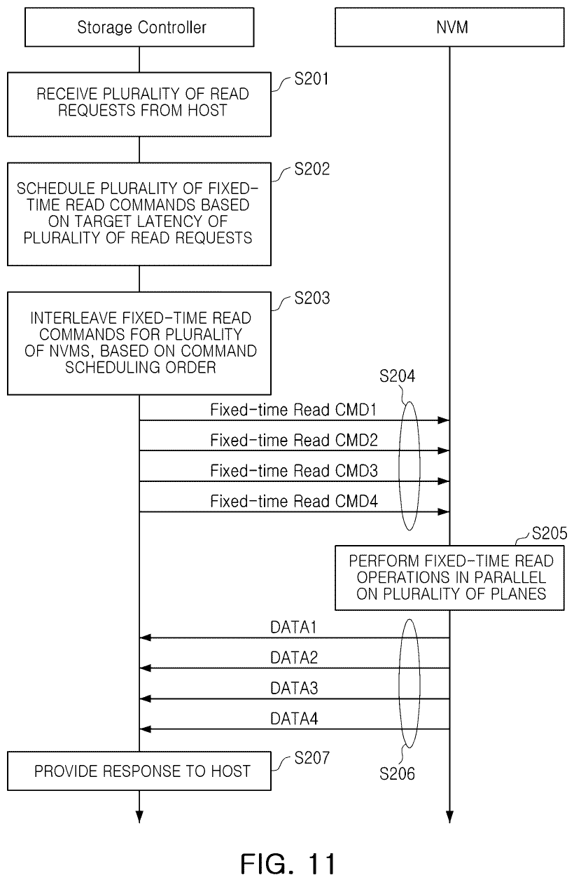

FIG. 11 is a flowchart illustrating an operation of the storage device according to some example embodiments.

FIG. 11 illustrates a transaction of a storage controller included in the storage device and one nonvolatile memory NVM.

In operation S201, the storage controller may receive a plurality of read requests from a host. The host may require (or request) a predetermined (or desired) level of QoS from the storage device. For example, the host may require (or request) the storage device to provide a response within a target latency for each of the read requests.

In operation S202, the storage controller may schedule a plurality of fixed-time read commands based on the target latency of the plurality of read requests.

For example, the storage controller may translate a logical address corresponding to each of the plurality of read requests into a physical address of the memory device, and translate the plurality of read requests into fixed-time read commands for one or more non-volatile memories. In some example embodiments, the storage controller may schedule the plurality of fixed-time read commands based on the target latency of the plurality of read requests, so that a fixed-time read command associated with a read request that should be processed earlier is provided to the non-volatile memory earlier.

In operation S203, the storage controller may interleave the plurality of fixed-time read commands for the plurality of non-volatile memories based on a command scheduling order. The plurality of nonvolatile memories may be connected to the storage controller via a plurality of channels, as described with reference to FIG. 2.

In some example embodiments, the storage controller may interleave commands for the nonvolatile memories connected to one channel, so that a fixed-time read command that should be processed earlier is provided earlier.

In operation S204, the storage controller may provide (or transmit) a plurality of fixed-time read commands to the nonvolatile memories. FIG. 11 illustrates a case in which the storage controller provides first to fourth fixed-time read commands to one nonvolatile memory NVM.

The first to fourth fixed-time read commands may be read commands for different planes of the nonvolatile memory NVM. The storage controller may provide (or transmit) the first to fourth fixed-time read commands to the nonvolatile memory NVM in sequence via the channel.

In operation S205, the nonvolatile memory NVM may perform fixed-time read operations corresponding to the first to fourth fixed-time read commands in parallel on a plurality of planes.

According to some example embodiments, the fixed-time read operations may have substantially the same completion period regardless of a bit level of the target subpage. For example, for each of the plurality of planes, a ready status may be changed to a busy status when the read operation is started, and the busy status may be restored to the ready status after the read operation time elapses and a delay time determined according to the bit level of the target subpage elapses. In each of the plurality of planes, busy status periods due to the read operation may be substantially the same.

According to some example embodiments, the fixed-time read operations performed on the plurality of planes may be completed in the same order as an order in which the fixed-time read commands are received.

In operation S206, the nonvolatile memory may output (or transmit) the first to fourth data items DATA1 to DATA4 corresponding to the first to fourth fixed time read commands, respectively, in the same order as an order in which the first to fourth fixed time read commands are received.

For example, the storage controller may provide data output commands for the plurality of planes in an order in which the fixed time read operations are completed. According to some example embodiments, since the fixed time read operations may be completed in the same order in the order in which the fixed time read commands are received, the first to fourth data items DATA1 to DATA4 may be output in the same order in an order which the first to fourth fixed time read commands are received.

In operation S207, the storage controller may provide a response to the plurality of read requests to the host based on the data, including the first to fourth data items DATA1 to DATA4.

According to some example embodiments, the storage controller may schedule a plurality of fixed-time read commands based on the latency of a plurality of read requests, and may obtain data items from nonvolatile memories in the order in which the plurality of fixed-time read commands are scheduled. For example, due to a difference in read operation time according to a bit level in a plurality of planes that may perform read operations in parallel, the problem that an output of data corresponding to a read command received earlier is delayed due to an output of data according to a read command received later may be prevented (or reduced).

Accordingly, the storage device may prevent (or reduce) the problem of an increase in the individual latency of read requests of the host, and may ensure QoS (or meet a desired QoS). For example, in the case in which there is a bottleneck phenomenon (or a delay) due to a channel sequentially outputting data from a nonvolatile memory NVM to the storage controller, or in the case in which the performance of the host is lower than that of the storage device, an increase in the latency of individual input/output requests may be suppressed (or effectively suppressed) with little effect on affecting the performance of the storage device.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FGPA), a System-on-Chip (SoC), a programmable logic unit, a microprocessor, application-specific integrated circuit (ASIC), etc.

The present inventive concepts are not limited to the above-described example embodiments and the accompanying drawings but are defined by the appended claims. Therefore, those of ordinary skill in the art may make various replacements, modifications, or changes, and combinations of example embodiments without departing from the scope of the present inventive concepts defined by the appended claims, and these replacements, modifications, or changes should be construed as being included in the scope of the present inventive concepts.

What is claimed is:

1. A nonvolatile memory, comprising:
a plurality of planes, each plane of the plurality of planes including a plurality of word lines, a plurality of bit lines, and a plurality of memory cells connected to the plurality of word lines and the plurality of bit lines, wherein the plurality of memory cells are multi-level cells;
an input/output controller configured to
receive commands and addresses through a channel,
input/output data through the channel, and
set each plane of the plurality of planes to a ready status or a busy status;
a control logic circuit configured to
control the plurality of planes based on the commands, and
detect a fixed-time read command, among the commands; and
a status delay logic configured to
determine a target plane and a bit level based on an address received with the fixed-time read command, and
determine a delay time based on the bit level,
wherein the input/output controller is configured to change the target plane from the ready status to the busy status when a read operation time is started in response to the fixed-time read command in the target plane, and
restore the target plane from the busy status to the ready status after the delay time has elapsed based on the read operation time having ended.

2. The nonvolatile memory of claim 1, wherein
the read operation time varies according to the bit level, and
a delay time according to the bit level is determined as a time at which busy status periods according to the bit level are same.

3. The nonvolatile memory of claim 2,
wherein the status delay logic is configured to:
determine a delay time corresponding to a bit level having a longest read operation time, among a plurality of bit levels of the multi-level cells, as ‘0,’ and
determine delay times of remaining bit levels among the plurality of bit levels as a time greater than ‘0’.

4. The nonvolatile memory of claim 1, wherein
the read operation time varies according to the bit level, and
a delay time according to the bit level is determined so that a difference between busy status periods according to the bit level is within a time required for receiving the commands.

5. The nonvolatile memory of claim 1,
wherein the status delay logic is configured to store a delay time based on the bit level.

6. The nonvolatile memory of claim 1,
wherein the input/output controller is configured to control status signals indicating the ready status or the busy status of each plane of the plurality of planes.

7. The nonvolatile memory of claim 1,
wherein the input/output controller is configured to output a status flag indicating the ready status or the busy status of the target plane in response to a status read command for the target plane.

8. The nonvolatile memory of claim 1,
wherein each plane of the plurality of planes is configured to perform a read operation in parallel in response to a plurality of fixed-time read commands sequentially received from the input/output controller.

9. The nonvolatile memory of claim 8,
wherein the input/output controller is configured to sequentially output data read from each plane of the plurality of planes in response to data output commands received through the channel.

10. The nonvolatile memory of claim 1, wherein
the multi-level cells are Triple Level Cells (TLC), and
the status delay logic is configured to determine the delay time to different times based on whether the bit level is a Most Significant Bit (MSB), a Central Significant Bit (CSB), or a Least Significant Bit (LSB) based on the received address.

11. The nonvolatile memory of claim 10,
wherein the status delay logic is configured to:
determine the delay time of the CSB as ‘0,’
determine the delay time of the LSB as a first time greater than ‘0,’ and
determine the delay time of the MSB as a second time greater than the first time.

12. The nonvolatile memory of claim 11,
wherein the input/output controller is configured to:
change a first plane from the ready status to the busy status when a read operation of the first plane is started in response to a normal read command, and
change the busy status of the first plane to the ready status after the read operation is completed.

13. A nonvolatile memory, comprising:
a plurality of planes, each plane of the plurality of planes including a plurality of word lines, a plurality of bit lines, and a plurality of memory cells connected to the plurality of word lines and the plurality of bit lines;
a control logic circuit configured to
control the plurality of planes based on commands, and
detect a plurality of fixed-time read commands for the plurality of planes; and
an input/output controller configured to
change the plurality of planes from a ready status to a busy status in an order in which the plurality of fixed-time read commands are received, and
restore the busy status to the ready status after respective delay times have elapsed based on respective read operation times of the plurality of fixed-time read commands having ended,
wherein an order in which the plurality of fixed-time lead commands are received and an order in which the plurality of planes are restored from the busy status to the ready status are consistent with each other.

14. The nonvolatile memory of claim 13,
wherein the plurality of planes are configured to perform read operations in parallel in response to the plurality of fixed-time read commands.

15. The nonvolatile memory of claim 13,
wherein the input/output controller is configured to sequentially output data items read from the plurality of planes in an order in which the plurality of planes are restored from the busy status to the ready status.

16. The nonvolatile memory of claim 13,
wherein a delay time of each of the plurality of planes is determined based on a bit level of target subpages indicated by addresses received together with the plurality of fixed-time read commands.

17. A storage device, comprising:
a plurality of nonvolatile memories, each nonvolatile memory of the plurality of nonvolatile memories including a plurality of planes;
a storage controller configured to control the plurality of nonvolatile memories; and
a plurality of channels configured to connect the storage controller and the plurality of nonvolatile memories,
wherein the storage controller is configured to
receive a plurality of read requests from a host,
schedule fixed-time read commands for the plurality of nonvolatile memories based on target latencies of the plurality of read requests, and
interleave the fixed-time read commands for the plurality of planes included in the plurality of nonvolatile memories based on a scheduled order, and
wherein each of the plurality of nonvolatile memories is configured to
perform fixed-time read operations in parallel on the plurality of planes in response to the fixed-time read commands, and
provide responses for the fixed-time read commands to the storage controller in a same order as an order in which the fixed-time read commands are received.

18. The storage device of claim 17,
wherein the storage controller is configured to provide fixed-time read commands for nonvolatile memories connected to one channel of the plurality of channels, to the one channel according to the scheduled order.

19. The storage device of claim 17,
wherein the storage controller is configured to:
provide a status read command for each plane of the plurality of planes to each nonvolatile memory of the plurality of nonvolatile memories, and
provide data output commands to each nonvolatile memory of the plurality of nonvolatile memories for the plurality of planes in an order in which ready statuses of the plurality of planes are detected.

20. The storage device of claim 17,
wherein the storage controller is configured to provide responses for the plurality of read requests to the host based on the responses received from the plurality of nonvolatile memories.
